(19) United States
(12) Patent Application Publication
(10) Pub. No.: US 2025/0385695 A1
(43) Pub. Date: Dec. 18, 2025

(54) CONTACTLESS ELECTRONIC DEVICE AND METHOD

(71) Applicant: STMicroelectronics International N.V., Geneva (CH)

(72) Inventors: Franck Montaudon, Meylan (FR); Julien Goulier, Grenoble (FR)

(21) Appl. No.: 19/206,831

(22) Filed: May 13, 2025

(30) Foreign Application Priority Data
Jun. 17, 2024 (FR) FR2406385

(51) Int. Cl. H04B 1/00; H03H 7/38

(52) U.S. Cl. CPC H04B 1/006; H03H 7/38

(57) ABSTRACT

The present description concerns an electronic device comprising an antenna and a circuit for matching the impedance of the antenna comprising first and second resistors that can be activated according to the value of a field received by the antenna and having values independent of the value of the field received by the antenna. A first terminal of the first resistor is coupled to a first terminal of the antenna, and a second terminal of the second resistor is coupled to a second terminal of the antenna different from the first terminal.

### CROSS-REFERENCE TO RELATED APPLICATIONS

This application claims priority to French Application No. 2406385, filed on Jun. 17, 2024, which application is hereby incorporated herein by reference.

### TECHNICAL FIELD

The present disclosure generally concerns electronic circuits, devices and methods. The present disclosure more particularly relates to electronic circuits, devices and methods adapted to implementing wireless links, such as wireless communications and/or wireless energy transfers.

### BACKGROUND

Wireless links are currently widely used to implement data communications, but also to perform energy transfers between two, or more than two, electronic devices.

It would be desirable to be able to improve, at least partly, certain aspects of wireless communications and/or of wireless energy transfers.

### SUMMARY

There exists a need for devices adapted to implementing higher-performance wireless communications.

There exists a need for devices adapted to implementing wireless communications in more accurate fashion.

There exists a need for devices adapted to implementing wireless communications with a very large number of different terminals.

There more particularly exists a need for devices adapted to implementing more efficient and more accurate near-field communications (NFC).

An embodiment overcomes all or part of the disadvantages of known electronic devices implementing wireless communication, such as a near-field communication.

An embodiment provides an electronic device adapted to implementing a more efficient and more accurate wireless communication.

An embodiment provides an electronic device adapted to implementing a more efficient and more accurate near-field communication.

An embodiment provides an electronic device comprising an antenna and a more accurate circuit for controlling the antenna impedance.

An embodiment further provides the method of controlling the impedance of the antenna of such a device.

An embodiment provides an electronic device comprising an antenna and a circuit for matching the impedance of the antenna comprising first and second resistors that can be activated according to the value of a field received by the antenna and having values independent of the value of the field received by the antenna. A first terminal of the first resistor is coupled to a first terminal of the antenna, and a second terminal of the second resistor is coupled to a second terminal of the antenna different from the first terminal.

Another embodiment provides a method of wireless communication between a terminal and a device comprising an antenna and a circuit for controlling the impedance of the antenna comprising first and second resistors that can be activated according to the value of a field received by the antenna and having values independent of the value of the field received by the antenna. A first terminal of the first resistor is coupled to a first terminal of the antenna, and a second terminal of the second resistor is coupled to a second terminal of the antenna different from the first terminal.

According to an embodiment, the first resistor is activated when the field received by the antenna has an amplitude exhibiting a low state, and the second resistor is activated when the field received by the antenna has an amplitude in a low state.

According to an embodiment, the first resistor is associated with a first switch controlled by a first control voltage depending on the field received by the antenna, and the second resistor is associated with a second switch controlled by a second control voltage depending on the field received by the antenna.

According to an embodiment, the first switch and the second switch are identical, and the first control voltage and the second control voltage are identical.

According to an embodiment, the first control voltage and the second control voltage are delivered by a circuit for delivering a voltage which is an image of the amplitude of a radio frequency field received by the antenna.

According to an embodiment, the device comprises a circuit for controlling the impedance seen by the antenna.

Still another embodiment provides a system comprising a previously-described device and a terminal.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, very schematically and partially in the form of blocks, a system adapted to implementing a wireless communication;

FIG. 2 shows in further detail an embodiment of a portion of a device of the system of FIG. 1;

FIG. 3 shows two series of curves illustrating the operation of the embodiment of FIG. 2; and

FIG. 4 shows curves illustrating in further detail the operation of the embodiment of FIG. 2.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

The embodiments described hereafter concern electronic devices adapted to implementing wireless data communications, such as near-field communications (NFC) or NFC communications. A near-field communication is based on the use of a radio frequency field to exchange data, and on the modulation of the frequency of this field to encode data. An electronic device adapted to receiving data originating from such a near-field communication is equipped with an antenna and with at least one signal extraction circuit. A circuit for managing the impedance of the antenna, or antenna impedance control circuit, may also be used to improve the signal reception performance of the device.

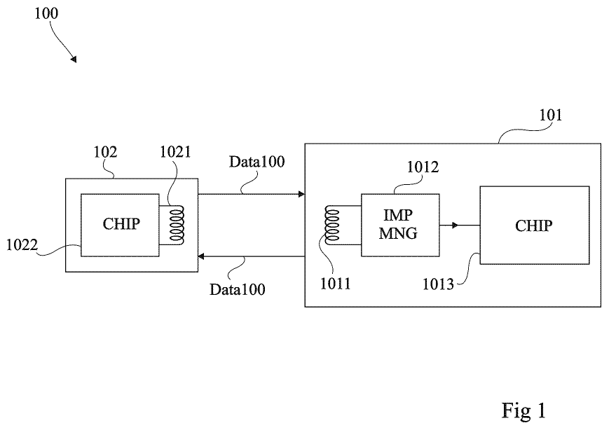

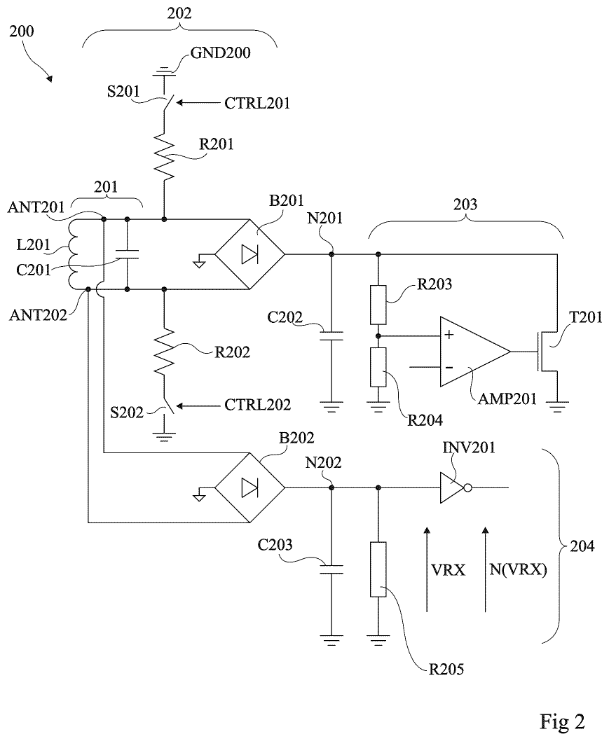

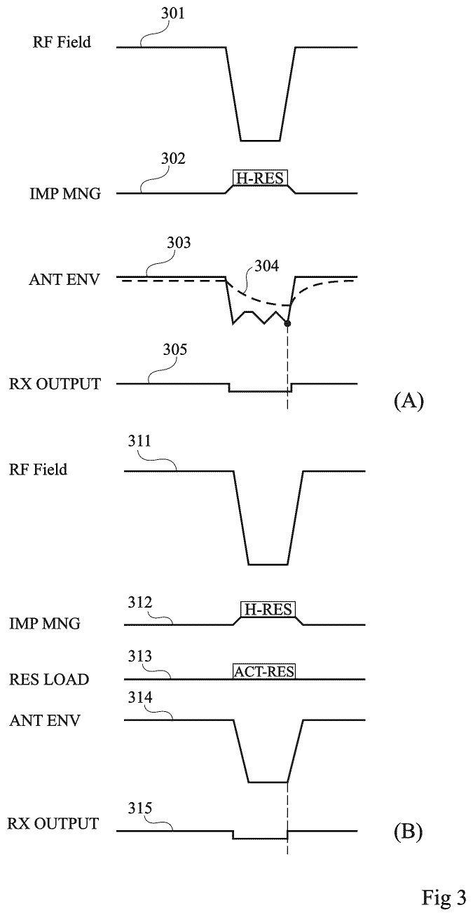

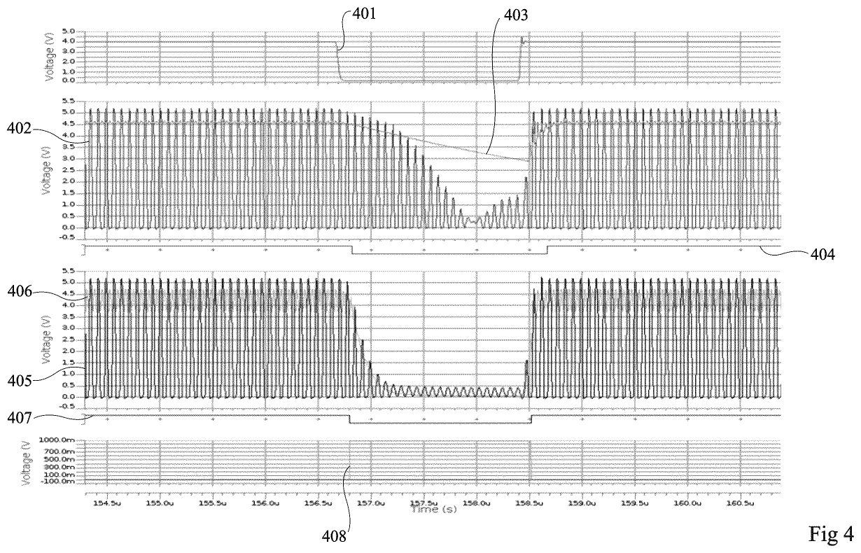

More particularly, the embodiments described hereafter more particularly concern an electronic device comprising an antenna and a circuit for controlling the impedance of the antenna enabling to improve the accuracy of the reception of a signal transmitted by a near field communication. These embodiments more specifically enable to improve the detection of a rising edge of the received signal. Such an embodiment is described in relation with FIGS. 1 and 2. Its operation is described in further detail in relation with FIGS. 3 and 4.

Further, the embodiments described hereabove are particularly adapted to being used in any type of industrial market where a wireless communication, and, more particularly a wireless communication using a radio frequency field, such as an NFC communication, is used. More particularly, such a device adapted to implementing a wireless communication may be intended for: the automotive industry, for example in the field of automotive electrification or in the field of advanced driver assistance systems (ADAS); the industrial sector, for example in the field of green energy, in the field of infrastructure electrification, of the Internet of Things (IoT), and of smart homes, where electric power and energy consumption and data exchange are key elements; and the personal electronics industry, for example in the field of mobile telephony and of the Internet of Things (IoT), as well as in high speed interfaces.

FIG. 1 shows, very schematically and partially in the form of blocks, an example of a system 100 comprising two electronic devices 101 and 102 adapted to communicating with each other by implementing a wireless communication.

According to an embodiment, electronic devices 101 and 102 are adapted to communicating data Data100 with each other by implementing a near-field communication, or NFC communication. For this purpose, each device 101, respectively 102, comprises at least one antenna 1011, respectively 1021, represented in FIG. 1 by a coil 1011, respectively 1021.

According to an embodiment, device 101 is adapted to receiving Data100 data from device 102. According to an example, device 101 is further adapted to supplying data Data100 to device 102.

For this purpose, according to an embodiment, device 101 comprises an embodiment of a circuit 1012 (IMP MNG) for controlling the impedance of antenna 1011. An example of embodiment of circuit 1012 is described in detail in relation with FIG. 2. Device 101 further comprises circuits 1013 (CHIP) for processing received data signals and, if relevant, data transmission circuits.

According to an embodiment, device 102 is adapted to sending data Data100 to device 101. According to an example, device 102 is further adapted to receiving data Data100 at device 101.

According to an example, device 102 comprises signal and data processing circuits 1022 (CHIP) enabling to send and, if relevant, to receive, data signals.

When data Data100 are sent by device 102 to device 101, device 102 emits a radio frequency field and modulates the amplitude of this field to encode data Data100. The antenna 1011 of device 101 receives this radio frequency field and decodes data Data100 by detecting the amplitude differences of the radio frequency field.

FIG. 2 shows an embodiment of a portion 200 of an electronic device of the type of the electronic device 101 described in relation with FIG. 1.

According to an example, portion 200 comprises an antenna 201 formed by an LC-type circuit in parallel. More particularly, antenna 201 comprises a coil L201 and a capacitor C201 coupled, preferably connected, in parallel with each other. Thus, a first terminal ANT201 of antenna 201 is coupled, preferably connected, to a first terminal of coil L201 and to a first terminal of capacitor C201, and a second terminal ANT202 of antenna 201 is coupled, preferably connected, to a second terminal of coil L201 and to a second terminal of capacitor C201.

According to an embodiment, portion 200 further comprises a circuit 202 for matching the impedance of antenna 201. Circuit 202 comprises two resistors, R201 and R202, that can be activated as a function of a voltage value received by antenna 201.

According to an example, a first terminal of resistor R201 is coupled, preferably connected, to the first terminal ANT201 of antenna 201, and a second terminal of resistor R201 is coupled to a node GND200 delivering a reference potential, for example the ground. To be able to be activated, resistor R201 is associated with a switch S201 controlled by a control voltage CTRL201. According to an example, a first terminal of switch S201 is coupled, preferably connected, to the second terminal of resistor R201, and a second terminal of switch S201 is coupled, preferably connected, to node GND200. According to an embodiment, resistors R201 and R202 have fixed resistance, resistivity, or impedance values totally independent of the amplitude of the radio frequency field received by antenna 201.

According to an example, a first terminal of resistor R202 is coupled, preferably connected, to the second terminal ANT202 of antenna 202, and a second terminal of resistor R202 is coupled to node GND200. To be able to be activated, resistor R202 is associated with a switch S202 controlled by a control voltage CTRL202. According to an example, a first terminal of switch S202 is coupled, preferably connected, to the second terminal of resistor R202, and a second terminal of switch S202 is coupled, preferably connected, to node GND200.

According to a preferred example, control voltages CTRL201 and CTRL202 control the opening and the closing of switches S201 and S202 at the same time. According to an embodiment, switches S201 and S202 are identical, and control voltages CTRL201 and CTRL202 are also identical.

According to an example, portion 200 further comprises a voltage rectifier circuit B201 for rectifying a voltage delivered by antenna 201. According to an example, the voltage rectifier circuit is a diode bridge comprising, for example, four diodes. A diode bridge assembly is an example of a voltage rectifier circuit well known to those skilled in the art, and it is thus not described in detail. Thus, a first input node of circuit B201 is coupled, preferably connected, to the first terminal ANT201 of antenna 201, and a second input node of circuit B201 is coupled, preferably connected, to the second terminal ANT202 of antenna 201. A first output node of circuit B201 is coupled, preferably connected, to node N201, and a second output node of circuit B201 is coupled, preferably connected, to node GND200.

According to an example, portion 200 further comprises a filtering capacitor C202. According to an example, a first terminal of capacitor C202 is coupled, preferably connected, to node N201, and a second terminal of capacitor C202 is coupled, preferably connected, to node GND200.

According to an example, portion 200 further comprises a circuit 203 for controlling the impedance seen by the antenna 201. According to an example, circuit 203 enables to match the impedance of node N201. According to an example, circuit 203 comprises two resistors R203 and R204, a voltage comparator AMP201, and a transistor T201. The two resistors R203 and R204 are coupled in series between node N201 and node GND200. According to an example, a first terminal of resistor R203 is coupled, preferably connected, to node N201. A second terminal of resistor R203 is coupled, preferably connected, to a first terminal of resistor R204. A second terminal of resistor R204 is coupled, preferably connected, to node GND200. A first+input terminal of comparator AMP201 is coupled, preferably connected, to the junction node of resistors R203 and R204. A second−input terminal of comparator AMP201 receives a reference potential Vref. An output terminal of comparator AMP201 is coupled, preferably connected, to a control terminal of transistor T201. A first conduction terminal of transistor T201 is coupled, preferably connected, to node N201, and a second conduction terminal of transistor T201 is coupled, preferably connected, to node GND200. According to an example, transistor T201 is a metal-oxide-semiconductor field-effect transistor, or MOSFET transistor, or MOS transistor. Further, transistor T201 is an N-channel MOS transistor, or N-type MOS transistor, or NMOS transistor.

According to an example, portion 200 further comprises a circuit 204 for delivering a voltage which is an image of the amplitude of a radio frequency field received by antenna 201. According to an example, circuit 204 comprises: a voltage rectifier circuit B202 of the type of the previously-described voltage rectifier circuit B201; a parallel RC-type circuit, comprising a capacitor C203 and a resistor R205; and an inverter circuit INV201.

Thus, a first input node of circuit B202 is coupled, preferably connected, to the first terminal ANT201 of antenna 201, and a second input node of circuit B202 is coupled, preferably connected, to the second terminal ANT202 of antenna 201. A first output node of circuit B202 is coupled, preferably connected, to node N202, and a second output node of circuit B202 is coupled, preferably connected, to node GND200.

A first terminal of capacitor C203 is coupled, preferably connected, to node N202, and a second terminal of capacitor C203 is coupled, preferably connected, to node GND200. A first terminal of resistor R205 is coupled, preferably connected, to node N202, and a second terminal of resistor R205 is coupled, preferably connected, to node GND200. A voltage VRX representing a smoothed image of the voltage delivered by antenna 201 is delivered between nodes N202 and GND200.

An input terminal of inverter circuit INV201 is coupled, preferably connected, to node N202. A voltage N (VRX) representing a smoothed and inverted image of the voltage delivered by antenna 201 is delivered between the output terminal of inverter circuit INV201 and node GND200.

The operation of portion 200 is described in relation with FIG. 3.

FIG. 3 comprises two series (A) and (B) of graphs illustrating the operation of the electronic device portion 200 described in relation with FIG. 2.

More precisely, series (A) illustrates the operation of a circuit of the type of the portion 200 described in relation with FIG. 2 but which does not comprise antenna impedance matching circuit 202. Series (B) illustrates the operation of the portion 2 described in relation with FIG. 2. The comparison of series (A) and (B) highlights the advantages of the use of antenna impedance matching circuit 202.

More particularly, series (A) comprises: a graph 301 (RF Field) representing an amplitude of a radio frequency field received by the antenna 201 of portion 200; a graph 302 (IMP MNG) representing operating modes of the impedance management circuit 203 of portion 200; graphs 303 (ANT ENV) and 304 representing an image voltage of a radio frequency field received by antenna 201; and a graph 305 (RX OUTPUT) representing data transmitted by the radio frequency field.

Further, series (B) comprises: a graph 311 (RF Field) representing an amplitude of a radio frequency field received by the antenna 201 of portion 200; a graph 312 (IMP MNG) representing operating modes of the impedance management circuit 203 of portion 200; a graph 313 (RES LOAD) representing operating modes of circuit 202; a graph 314 (ANT ENV) representing a voltage which is an image of a radio frequency field received by antenna 201; and a graph 315 (RX OUTPUT) representing data transmitted by the radio frequency field.

Graphs 301 and 311 show that the radio frequency field received by antenna 201 has an amplitude which has, in a first period, a high state, then, in a second period, a low state, and finally, in a third period, a high state. It is spoken of a high state when the amplitude is higher than a first threshold value. It is spoken of a low state when the amplitude is lower than a second threshold value, which is lower than the first threshold value.

When the radio frequency field is in a low state, impedance management circuit 203 switches to a high-impedance mode (H-RES), since the voltage collected by the antenna is lower than the reference voltage. This is illustrated by graphs 302 and 312.

In particular, in the case of series (A), the image voltage of the field received by the antenna switches, when the field is in a low state, to a low state. However, graphs 303 and 304 show that this voltage can exhibit oscillation phenomena in the low state, which may distort the detection of the data transmitted by the radio frequency field. In other words, this oscillation effect may make the detection of a rising edge inaccurate, and cause detection delays. Graph 303 shows an oscillation phenomenon appearing on a voltage delivered by a circuit of the type of the circuit 204 described in relation with FIG. 2. Graph 304 illustrates, in dotted lines, the value of this voltage that is taken into account to obtain the data transmitted by the radio frequency field.

In the case of series (B), graph 313 indicates that, when the radio frequency field is at a low level, circuit 204 activates resistors R201 and R202 (ACT-RES). By activating these resistors, the antenna impedance is set to a high value, which results in decreasing, or even in preventing, the occurrence of oscillation phenomena in voltage VRX.

This advantage can be seen by comparing the time of the rising edge shown in graphs 305 and 315.

FIG. 4 is a set of curves further illustrating the operation of the portion 200 described in relation with FIG. 2.

The curves of FIG. 4 have been obtained by the inventors during a test implementation phase. FIG. 4 highlights the advantages of the use of antenna impedance matching circuit 202.

FIG. 4 comprises: a curve 401 representing the amplitude of a radio frequency field received by the antenna of portion 200; a curve 402 representing the voltage delivered, on reception of the radio frequency field, by an antenna of a circuit comprising no circuit 202; a curve 403 representing the value of the voltage of curve 402 which has to be taken into account to obtain the data transmitted by the radio frequency field; a curve 404 representing an output data signal obtained from the voltage of curve 402; a curve 405 representing the voltage delivered, on reception of the radio frequency field, by an antenna 201 of the portion 200 of FIG. 2 comprising circuit 202; a curve 406 representing the value of the voltage of curve 405 which has to be taken into account to obtain the data transmitted by the radio frequency field; a curve 407 representing an output data signal obtained from the voltage of curve 405; and a curve 408 representing the variation of a voltage for controlling circuit 202.

Like the two series (A) and (B) of FIG. 3, the curves show that the use of a circuit of the type of circuit 202 enables to limit phenomena of oscillations in the amplitude of the voltage collected by the antenna when the voltage is in the low state, and thus enables to make the detection of a rising edge more accurate.

It should be noted that the detection of a rising edge is an important functionality, in particular, during the implementation of a near-field communication using a type-A communication protocol. In this case, the detection of a rising edge during a data transmission may enable to start a counter which enables to measure the time between exchanged messages. Having a device capable of more accurately detecting a rising edge enables, for example, to increase its compatibility with other electronic devices.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given above.

What is claimed is:

1. An electronic device comprising:
an antenna; and
a circuit configured to match an impedance of the antenna, the circuit comprising first and second resistors activatable in accordance with a value of a radio frequency field received by the antenna, and having values independent of the value of the radio frequency field received by the antenna, wherein:
a first terminal of the first resistor is coupled to a first terminal of the antenna; and
a second terminal of the second resistor is coupled to a second terminal of the antenna different from the first terminal of the antenna.

2. The device according to claim 1, wherein:
the first resistor is configured to be activated in response to the radio frequency field received by the antenna having an amplitude exhibiting a low state; and
the second resistor is configured to be activated in response to the radio frequency field received by the antenna having the amplitude in the low state.

3. The device according to claim 1, wherein:
the first resistor is coupled to a first switch controlled by a first control voltage based on the radio frequency field received by the antenna; and
the second resistor is coupled to a second switch controlled by a second control voltage based on the radio frequency field received by the antenna.

4. The device according to claim 3, wherein:
the first switch and the second switch are identical; and
the first control voltage and the second control voltage are identical.

5. The device according to claim 3, further comprising a first circuit configured to deliver the first and second control voltages as images of an amplitude of the radio frequency field received by the antenna.

6. The device according to claim 1, wherein the device further comprises a first circuit configured to control a first impedance seen by the antenna.

7. The device according to claim 1, further comprising a voltage rectifier coupled between the first terminal of the first resistor and the second terminal of the second resistor.

8. A method of wireless communication between a terminal and a device, the device comprising an antenna and a circuit, the circuit comprising a first resistor having a first terminal coupled to a first terminal of the antenna, and a second resistor having a second terminal coupled to a second terminal of the antenna different from the first terminal of the antenna, the method comprising:
receiving, by the antenna, a radio frequency field, the first and second resistors having values independent of a value of the radio frequency field received by the antenna; and
controlling, by the circuit, an impedance of the antenna, the controlling comprising:
activating the first resistor in accordance with the value of the radio frequency field received by the antenna; and
activating the second resistor in accordance with the value of the radio frequency field received by the antenna.

9. The method according to claim 8, further comprising:
activating the first resistor in response to the radio frequency field received by the antenna having an amplitude exhibiting a low state; and
activating the second resistor in response to the radio frequency field received by the antenna having the amplitude in the low state.

10. The method according to claim 8, further comprising:
controlling, with a first control voltage, a first switch coupled to the first resistor, based on the radio frequency field received by the antenna; and
controlling, with a second control voltage, a second switch coupled to the second resistor, based on the radio frequency field received by the antenna.

11. The method according to claim 10, wherein:
the first switch and the second switch are identical; and
the first control voltage and the second control voltage are identical.

12. The method according to claim 10, further comprising delivering, by a first circuit, the first and second control voltages as images of an amplitude of the radio frequency field received by the antenna.

13. The method according to claim 8, further comprising controlling, by a first circuit, a first impedance seen by the antenna.

14. A system comprising:
an electronic device comprising:
an antenna; and
a circuit configured to match an impedance of the antenna, the circuit comprising first and second resistors activatable in accordance with a value of a radio frequency field received by the antenna, and having values independent of the value of the radio frequency field received by the antenna, wherein:
a first terminal of the first resistor is coupled to a first terminal of the antenna; and
a second terminal of the second resistor is coupled to a second terminal of the antenna different from the first terminal of the antenna; and
a terminal configured to wirelessly communicate with the device.

15. The system according to claim 14, wherein:
the first resistor is configured to be activated in response to the radio frequency field received by the antenna having an amplitude exhibiting a low state; and
the second resistor is configured to be activated in response to the radio frequency field received by the antenna having the amplitude in the low state.

16. The system according to claim 14, wherein:
the first resistor is coupled to a first switch controlled by a first control voltage based on the radio frequency field received by the antenna; and
the second resistor is coupled to a second switch controlled by a second control voltage based on the radio frequency field received by the antenna.

17. The system according to claim 16, wherein:
the first switch and the second switch are identical; and
the first control voltage and the second control voltage are identical.

18. The system according to claim 16, wherein the device further comprises a first circuit configured to deliver the first and second control voltages as images of an amplitude of the radio frequency field received by the antenna.

19. The system according to claim 14, wherein the device further comprises a first circuit configured to control a first impedance seen by the antenna.

20. The system according to claim 14, wherein the device further comprises a voltage rectifier coupled between the first terminal of the first resistor and the second terminal of the second resistor.
